(19) United States
(12) Patent Application Publication
(10) Pub. No.: US 2005/0127489 A1
(43) Pub. Date: Jun. 16, 2005

(54) Microelectronic device signal transmission by way of a lid

(76) Inventors: Debendra Mallik, Chandler, AZ (US); Chris Baldwin, Chandler, AZ (US); Brent Stone, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/733,183

(22) Filed: Dec. 10, 2003

(51) Int. Cl. H01L 21/48; H01L 23/02

(52) U.S. Cl. 257/686; 438/109; 257/778; 438/108

(57) ABSTRACT

A microelectronic device package including an electrically conductive lid having an attachment surface, a substrate having an attachment surface, at least one interconnect extending between the lid attachment surface and the substrate attachment surface, at least one microelectronic die disposed between the lid attachment surface and the substrate attachment surface, and the substrate having at least one first conductive trace extending between the electrically conductive first interconnect and the microelectronic die. The microelectronic device package allows for the use of the electrically conductive lid as a path for conducting signals (preferably power or ground) to and/or from a microelectronic die.

### BACKGROUND OF THE INVENTION

1. Field of the Invention

The present invention relates to apparatus and methods for the transmission of signals to and/or from a microelectronic device. In particular, the present invention relates to delivering signals to and/or from a microelectronic device through a lid.

2. State of the Art

Higher performance, lower cost, increased miniaturization of integrated circuit components, and greater packaging densities of integrated circuits are ongoing goals of the computer industry. As these goals are achieved, microelectronic dice become smaller, and, with higher performance, comes an ever increasing number of interconnects, such as pins, lands, and balls, on the active surface of a microelectronic die.

Microelectronic dice are typically mounted on substrates, called as “interposers”, for packaging purposes, as is known to those skilled in the art. An interposer typical comprises a substrate core (e.g., bismaleimide triazine resin, FR4, polyimide materials, and the like) having dielectric layers (e.g., epoxy resin, polyimide, bisbenzocyclobutene, and the like) and conductive traces (e.g., copper, aluminum, and the like) on a top surface thereof to form a top trace network, and dielectric layers and conductive traces on a bottom surface thereof to form a bottom trace network. To achieve electrical interconnect between the top trace network and the bottom trace network, holes are drilled through the substrate core in specific locations and these holes are plated with a conductive material.

The high interconnect counts on the microelectronic dice requires ever larger and larger interposers. However, interposers are one of the most expensive components of a microelectronic package, and their expensive increases proportionally to its size. Thus, in the pursuit of lower costs, advancements which reduce the cost of interposers are continually sought by the microelectronic device industry.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1c are side cross-sectional views of a fabrication technique for an embodiment of a microelectronic die package, according to the present invention;

FIG. 2 is a side cross-sectional view of a microelectronic die assembly formed with the microelectronic die package illustrated in FIG. 1c, according to the present invention;

FIGS. 3a-3c are side cross-sectional views of a fabrication technique for another embodiment of a microelectronic die package, according to the present invention;

FIG. 4 is a plane view of the heat dissipation assembly, along line 4-4 of FIG. 3b, according to the present invention;

FIG. 5 is a side cross-sectional view of an embodiment of a microelectronic die package, according to the present invention;

FIG. 6 is a side cross-sectional view of a microelectronic die assembly formed with the microelectronic die package illustrated in FIG. 3c, according to the present invention;

FIG. 7 is an oblique view of a hand-held device having a microelectronic assembly of the present integrated therein, according to the present invention; and

FIG. 8 is an oblique view of a computer system having a microelectronic assembly of the present integrated therein, according to the present invention.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention relates to using an electrically conductive lid as a path for conducting signals (preferably power or ground) to and/or from a microelectronic die. Doing such, allows for the delivery of high electrical current driven by higher power and lower voltage and/or fewer conductive traces needed in a substrate and thereby reduces the size and, thus, the cost of the substrate. Furthermore, as the lid is significantly thicker than the conductive traces on or in the substrate, the invention can provide a low resistance electrical power path to a microelectronic die reducing power distribution on the substrate and reducing DC voltage drop between the microelectronic die and external components, such as a motherboard.

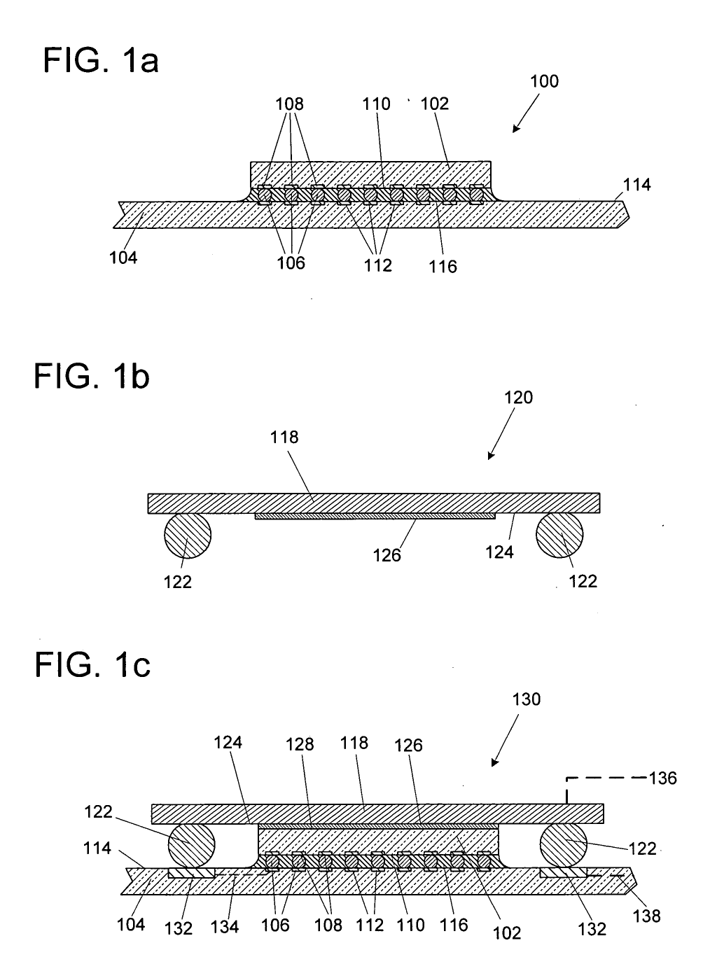

FIG. 1a illustrates a microelectronic die assembly 100 comprising a microelectronic die 102 (illustrated as a flip chip) physically and electrically attached to an attachment surface 114 of a substrate 104 (such as an interposer, a motherboard, or the like) by a plurality of conductive bumps 106, such as solder balls, conductive particle filled polymers, and the like, extending between pads 108 on an active surface 110 of the microelectronic die 102 and lands 112 on the substrate attachment surface 114. To mechanically and physically reinforce the conductive bumps 106 connecting the microelectronic die pads 108 and the substrate lands 112, an underfill material 116, such as an epoxy material, is disposed therebetween. The microelectronic die 102 may include, but is not limited to central processing units (CPUs), chipsets, memory devices, ASICs, and the like.

FIG. 1b illustrates a lid assembly 120 comprising a lid 118 and at least one interconnect 122 is disposed proximate an attachment surface 124 of the lid 118. The interconnect 122 may be any electrically conductive material, including but not limited to metal (e.g., lead, tin, silver, copper, aluminum, alloys thereof, etc.) and conductive particle filled polymers. If a metal is used for the interconnect 122, wetting layers (not shown), such gold or the like (as known in the art), may be formed prior to the attachment of the interconnect 122 to assist in attachment thereof. The lid 118 should be constructed from an electrically conductive material, such as copper (preferred), copper alloys, aluminum, aluminum alloys, and the like. Furthermore, the lid 118 may be an electrically and thermally conductive heat dissipation device, as will be understood to those skilled in the art. The lid 118 is preferably a flat plate having a substantially planar attachment surface 124. Using a flat plate greatly simplifies the fabrication of the lid 118, as compared to complex shapes used in the industry. Additionally, if the lid 118 also functions as a heat dissipation device, a flat plate allows for easily varying the thickness of the lid 118 without significant cost implications, and varying the thickness of the heat dissipating lid 118 allows the management of thermal performance, weight, and overall package thickness depending on application.

However, it is understood that the lid 118 is not limited to a flat plate. If the lid 18 is also a heat dissipation device, it may be of any appropriate shape, including high surface area (e.g., finned) heat sinks, and may include a heat pipe, thermoelectric coolers, and cold plates (refrigeration or liquid cooled), so long as it is electrically conductive.

A thermal interface material 126 may be disposed on the lid attachment surface 124, preferably in a central portion of the lid attachment surface 124. The thermal interface material 126 should have high thermal conductivity and may include, but is not limited to, thermal grease, phase-change material, metal filled polymer matrix, solder (alloys of lead, tin, indium, silver, copper, and the like), and other such materials known in the art.

FIG. 1c illustrates the lid assembly 120 of FIG. 1b attached to the microelectronic die assembly 100 of FIG. 1a to form a microelectronic device package 130. The thermal interface material 126 is placed in contact with a back surface 128 of the microelectronic die 102 and, substantially simultaneously, the interconnect 122 is brought into contact with the substrate attachment surface 114, preferably into contact with at least one interconnect land 132, such as a metal pad, on the substrate attachment surface 114. The interconnect land 132 is connected to a conductive trace (represented by dashed line 134), which is connected to at least one substrate land 112.

The interconnect land 132 may comprise a reflowable material and the assembly may be heated to reflow the interconnects 122 and/or interconnect lands 132, thereby adhering the interconnects 122 to the substrate attachment surface 114, as well as lid attachment surface 124. Although the interconnects 122 are shown as being spheres, as it is understood that they may be any appropriate shape and, also, the reflow step can deform the shape of the resulting interconnects.

It is, of course, understood that the thermal interface material 126 could be disposed on the microelectronic die back surface 128, rather than on the lid attachment surface 124, and/or the plurality of interconnects 122 could be disposed on the substrate attachment surface 114, rather than on the lid attachment surface 124, prior to the attachment of the lid 118.

At least one electronic line provides an electronic signal (i.e., power, ground, and I/O signal) to the lid 118. The electronic line (shown as dashed line 136) may be attached directly to the lid 118. Thus, as shown in FIG. 1c, the signal may be delivered to the microelectronic die 102 by way of the interconnect 122, the interconnect land 132, the conductive trace 134, the substrate land 112, the conductive bump 106, and the microelectronic die pad 108. Furthermore, as shown in FIG. 1c, the electronic line (shown as dashed line 138) may be within or on the substrate 104 and connected to at least one interconnect 122, thereby providing an electronic signal path to the lid 118. The lid may then be used to distribute the electronic signal, as previously discussed. It is, of course, understood that every interconnect 122 connected to the lid 118 will transmit (or receive) the same electronic signal.

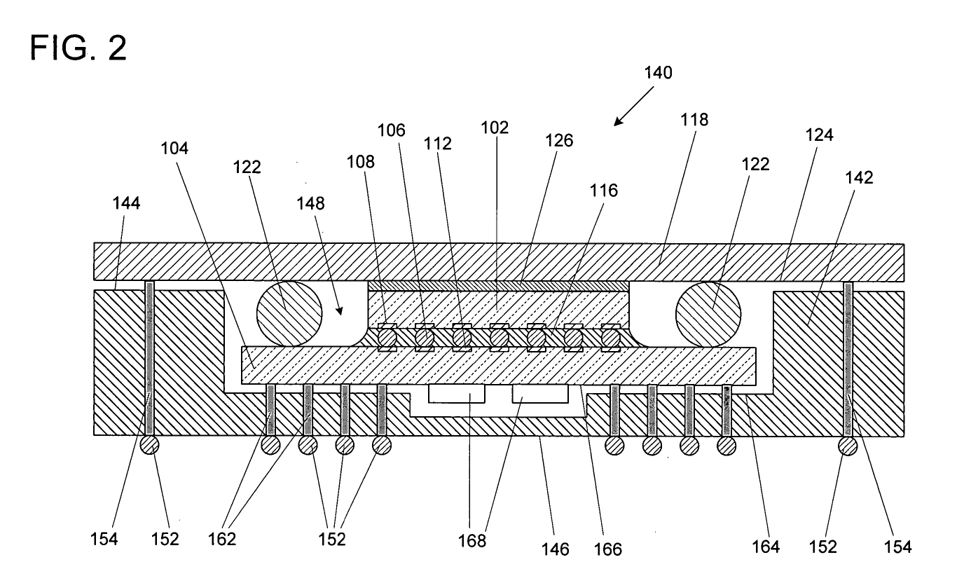

The microelectronic device package 130 of FIG. 1c may be incorporated into a socket 142 as shown in FIG. 2 to form a socketed microelectronic device assembly 140. The socket 142 comprises a first surface 144 and an opposing second surface 146 with a recess 148 formed therein extending from the socket first surface 144. The substrate 104 and microelectronic die 102 are disposed in the socket recess 148 with the lid attachment surface 124 proximate the socket first surface 144. The socket second surface 146 has a plurality of external contacts 152 attached thereto. These external contacts 152 generally make contact with an external device (not shown), such as a motherboard.

The socket 142 includes at least on one first signal line 154 contacting at least one external contact 152, extending through the socket 142 from the socket second surface 146 to the socket first surface 144, and contacting the lid 118. Thus, a signal may delivered through the first signal line 154 to the lid 118, then from the lid 118 to the microelectronic die 102 in a manner previously described.

The socket 142 may further include at least one second signal line 162 contacting at least one external contact 152, extending through the socket 142 from the socket second surface 146 to a bottom 164 of the socket recess 148, and contacting a second surface 166 of the substrate 104. It is, of course, understood that the first signal line 154 and the second signal line 162 may comprise a combination of conductive elements and may take a circuitous route through the socket 142, rather than the illustrated straight signal lines, as will understood by those skilled in the art.

As will be understood by those skilled in the art, the substrate 104 may include a substrate core (e.g., bismaleimide triazine resin, FR4, polyimide materials, and the like) having dielectric layers (e.g., epoxy resin, polyimide, bisbenzocyclobutene, and the like) and conductive traces (e.g., copper, aluminum, and the like) on a top surface thereof to form a top trace network, and dielectric layers and conductive traces on a bottom surface thereof to form a bottom trace network. To achieve electrical interconnect between the top trace network and the bottom trace network, holes are drilled through the substrate core in specific locations and these holes are plated with a conductive material. The resulting plated holes are known in the art as “plated through-hole (PTH)” vias. Thus, an electronic signal may be delivered and/or received through the second signal line 162, through the substrate 104, and to the microelectronic die 102 by way of the substrate lands 112, conductive bumps 106, and microelectronic die pads 108. Additionally, passive devices 168, such as capacitors, resistors, and the like may be attached to the substrate second surface 166.

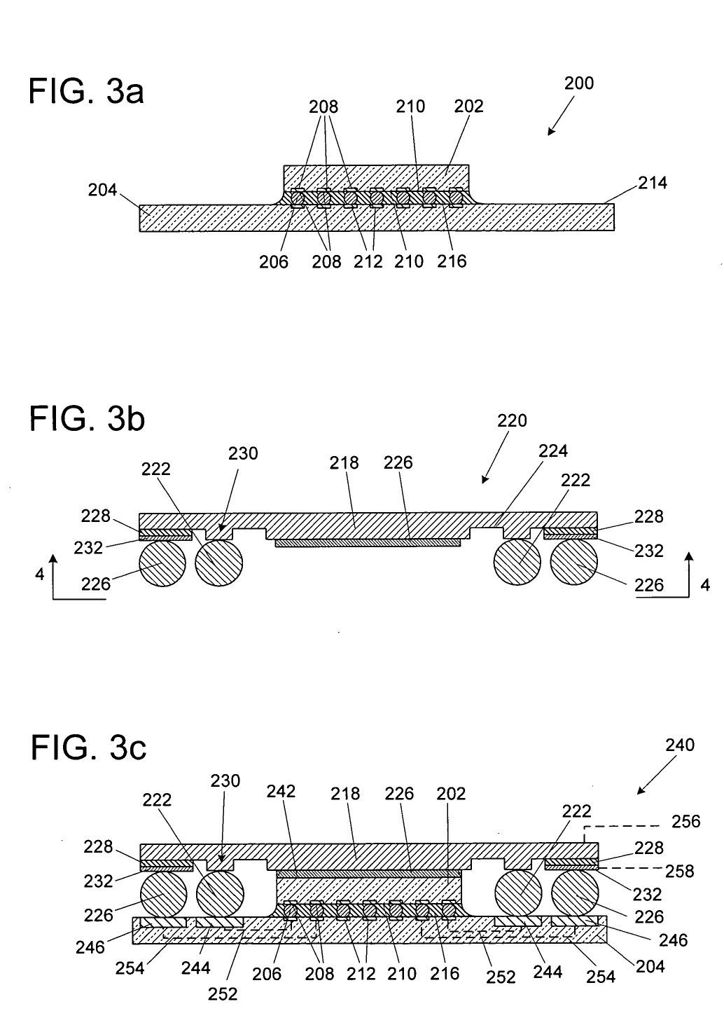

FIG. 3a illustrates another microelectronic die assembly 200 according to the present invention comprising a microelectronic die 202 (illustrated as a flip chip) physically and electrically attached to an attachment surface 214 of a substrate 204 (such as an interposer, a motherboard, or the like) by a plurality of conductive bumps 206, such as solder balls, conductive particle filled polymers, and the like, extending between pads 208 on an active surface 210 of the microelectronic die 202 and lands 212 on the substrate attachment surface 214. To mechanically and physically reinforce the conductive bumps 206 connecting the microelectronic die pads 208 and the substrate lands 212, an underfill material 216, such as an epoxy material, is disposed therebetween. The microelectronic die 202 may include, but is not limited to central processing units (CPUs), chipsets, memory devices, ASICs, and the like.

FIG. 3b illustrates a lid assembly 220 comprising a lid 218, at least one first interconnect 222 disposed on and in electrical contact with an attachment surface 224 of the lid 218, and at least one second interconnect 226 disposed proximate, but electrically isolated from an attachment surface 224 of the lid 218. The second interconnects 226 are electrically isolated by a dielectric layer 228 disposed on the lid attachment surface 224. An electrically conductive signal trace 232 is disposed on the dielectric layer 228 and the second interconnect 226 is attached to the conductive signal trace 232. The lid attachment surface 224 may have height variations 230 thereon such that the first interconnects 222 and the second interconnects 226 may be substantially the same size in size or height.

The first interconnect 222 and the second interconnect 226 may be any electrically conductive material, including but not limited to metal (e.g., lead, tin, silver, copper, aluminum, alloys thereof, etc.) and conductive particle filled polymers. If a metal is used for the first interconnect 222 and/or the second interconnect 226, wetting layers (not shown), such gold or the like (as known in the art), may be formed prior to the attachment of the first interconnect 222 and/or second interconnect 226 to assist in attachment thereof. The lid 218 should be constructed from a thermally conductive and electrically conductive material, such as copper, copper alloys, aluminum, aluminum alloys, and the like.

A thermal interface material 234 may be disposed on the lid attachment surface 224, preferably in a central portion of the lid attachment surface 224. The thermal interface material 234 should have high thermal conductivity and may include, but is not limited to, thermal grease, phase-change material, metal filled polymer matrix, solder (alloys of lead, tin, indium, silver, copper, and the like), and other such materials known in the art.

FIG. 3c illustrates the heat dissipation assembly 220 of FIG. 3b attached to the microelectronic die assembly 200 of FIG. 3a to form a microelectronic device package 240. The thermal interface material 234 is placed in contact with a back surface 242 of the microelectronic die 202 and, substantially simultaneously, the first interconnect 222 is brought into contact with the substrate attachment surface 214, preferably into contact with at least one first interconnect land 244, such as a metal pad, on the substrate attachment surface 214 and the second interconnect 226 is brought into contact with the substrate attachment surface 214, preferably into contact with at least one second interconnect land 246, such as a metal pad, on the substrate attachment surface 214. The first interconnect land 244 is connected to a first conductive trace (represented by dashed line 252), which is connected to at least one substrate land 212. The second interconnect 226 is connected to a second conductive trace (represented by dashed line 254), which is connected to at least one substrate land 212.

The first interconnect land 244 and second interconnect land 246 may comprise a reflowable material and the assembly may be heated to reflow the first interconnects 222 and second interconnects 226 and/or the first interconnect lands 244 and second interconnect lands 246, thereby adhering the first interconnects 222 to the substrate attachment surface 214, as well as the lid attachment surface 224 and adhering the second interconnects 226 to the conductive signal traces 232.

At least one electronic line provides a first electronic signal (i.e., power, ground, and I/O signal) to the lid 218. The electronic line (shown as dashed line 256) may be attached directly to the lid 218. Thus, as shown in FIG. 3c, the first electronic signal may be delivered to the microelectronic die 202 by way of the first interconnect 222, the first interconnect land 244, the first conductive trace 252, the substrate land 212, the conductive bump 206, and the microelectronic die pad 208. It is, of course, understood that every first interconnect 222 connected to the lid 218 will transmit (or receive) the same electronic signal.

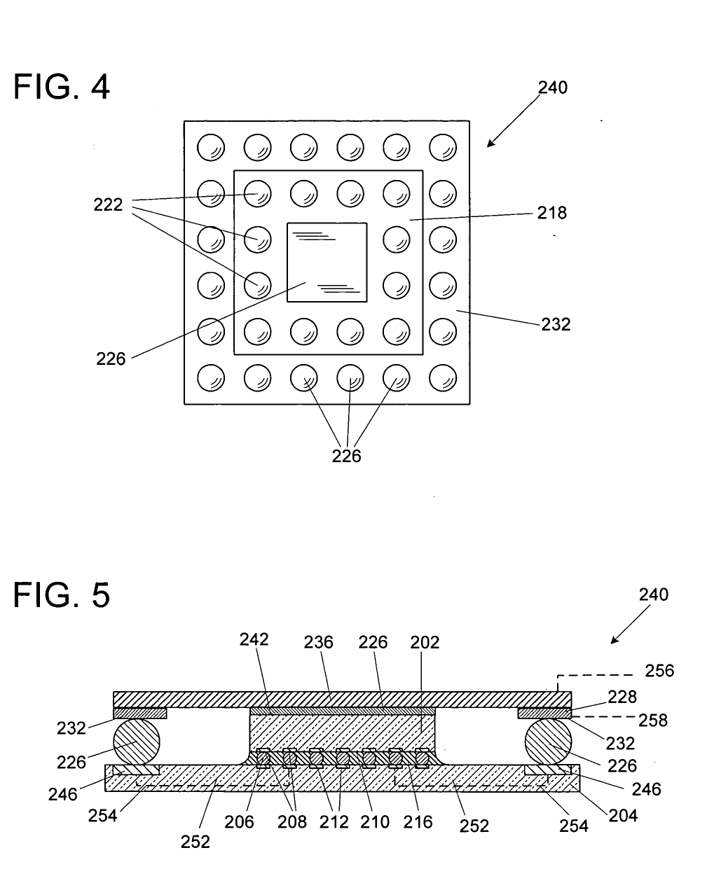

Furthermore, as shown in FIG. 3c, at least one electronic line provides a second electronic signal (i.e., power, ground, and I/O signal) to the conductive signal trace 232. An electronic line (shown as dashed line 258) may directly connect to the conductive signal trace 232, thereby proving the signal to the microelectronic die 202 by way of the second interconnect 226, the second interconnect land 246, the second conductive trace 254, the substrate land 212, the conductive bump 206, and the microelectronic die pad 208. As shown in FIG. 4, the conductive signal trace 232 may contact all of the second interconnects 226, thereby providing the same signal to all. Of course, it is understood that the invention includes any number of conductive signal traces 232 having differing discrete signals delivered to or received therefrom. It is, of course, understood that the conductive signal trace(s) 232 could be the only conductive element(s) of the lid (i.e., the lid being an insulative lid 236 and all signal being delivered with conductive signal traces 232), as shown in FIG. 5.

The microelectronic die package 240 of FIG. 3c may be incorporated into a socket 262 as shown in FIG. 5 to form a socketed microelectronic device package 260. The socket 262 comprises a first surface 264 and an opposing second surface 266 with a recess 268 formed therein extending from the socket first surface 264. The substrate 204 and microelectronic die 202 are disposed in the socket recess 268 with the lid 218 proximate the socket first surface 264. The socket second surface 266 has a plurality of external contacts 272 attached thereto. These external contacts 272 generally make contact with an external device (not shown), such as a motherboard.

The socket 262 includes at least on one first signal line 274 contacting at least one external contact 272, extending through the socket 262 from the socket second surface 266 to the socket first surface 264, and contacting the lid 218. Thus, a signal may delivered through the first signal line 274 to the lid 218, then from the lid 218 to the microelectronic die 202 in a manner previously described. The socket 262 may further include at least one second signal line 282 contacting at least one external contact 272, extending through the socket 262 from the socket second surface 266 to a bottom 284 of the socket recess 268, and contacting a second surface 286 of the substrate 204.

The socket 262 also includes at least on one third signal line 292 contacting at least one external contact 272, extending through the socket 262 from the socket second surface 266 to the socket first surface 264, and contacting the conductive signal trace 232. Thus, a signal may delivered through the third signal line 292 to the conductive signal trace 232, then from the conductive signal trace 232 to the microelectronic die 202 in a manner previously described. It is, of course, understood that the first signal line 274, the second signal line 282, and the third signal line 292 may comprise a combination of conductive elements and may take a circuitous route through the socket 262, rather than the illustrated straight signal lines, as will understood by those skilled in the art.

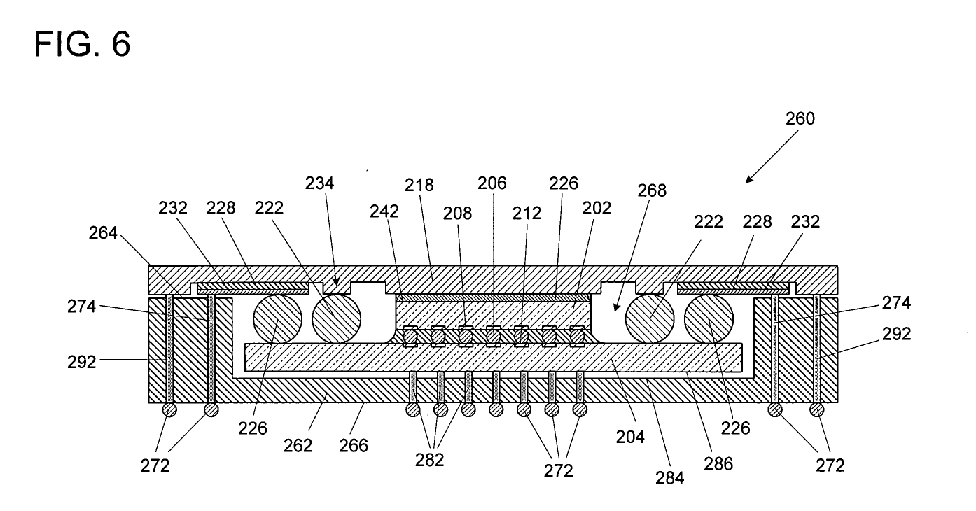

The packages formed by the present invention may be used in a hand-held device 310, such as a cell phone or a personal data assistant (PDA), as shown in FIG. 6. The hand-held device 310 may comprise an external substrate 320 with at least one of the microelectronic device package 130 of FIG. 1c, the socketed microelectronic device package 140 of FIG. 2, the microelectronic device package 240 of FIG. 3c, and the socketed microelectronic device package 260 of FIG. 5 collectively represented as element 330 attached thereto, within a housing 340. The external substrate 320 may be attached to various peripheral devices including an input device, such as keypad 350, and a display device, such an LCD display 360.

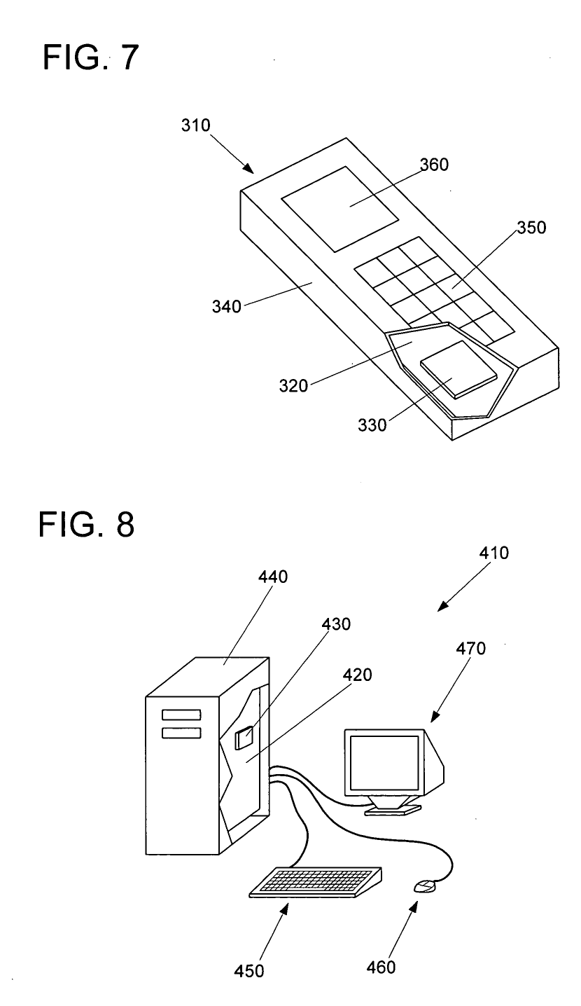

The microelectronic device assemblies formed by the present invention may also be used in a computer system 410, as shown in FIG. 7. The computer system 410 may comprise an external substrate or motherboard 420 with at least one of the microelectronic device package 130 of FIG. 1c, the socketed microelectronic device package 140 of FIG. 2, the microelectronic device package 240 of FIG. 3c, and the socketed microelectronic device package 260 of FIG. 5 collectively represented as element 430 attached thereto, within a housing or chassis 440. The external substrate or motherboard 420 may be attached to various peripheral devices including inputs devices, such as a keyboard 450 and/or a mouse 460, and a display device, such as a CRT monitor 470.

Having thus described in detail embodiments of the present invention, it is understood that the invention defined by the appended claims is not to be limited by particular details set forth in the above description, as many apparent variations thereof are possible without departing from the spirit or scope thereof.

1. A microelectronic device package, comprising:
an electrically conductive lid having an attachment surface;
a substrate having an attachment surface;
at least one electrically conductive first interconnect extending between said lid attachment surface and said substrate attachment surface;
at least one microelectronic die disposed between said lid attachment surface and said substrate attachment surface; and
said substrate having at least one first conductive trace extending between said electrically conductive first interconnect and said microelectronic die.

2. The microelectronic device package of claim 1, further including a first signal line in electrical communication with said electrically conductive lid.

3. The microelectronic device package of claim 1, wherein said electrically conductive lid comprises thermally conductive heat dissipation device.

4. The microelectronic device package of claim 3, further comprising a thermal interface material disposed between said heat dissipation device and a back surface of said at least one microelectronic die.

5. The microelectronic device package of claim 1, further comprising:
a socket having a first surface, a second surface opposing said first surface; and a recess extending into said socket from said socket first surface;
said substrate and said microelectronic die substantially residing in said socket recess; and
a portion of said lid extending proximate said socket first surface.

6. The microelectronic device package of claim 5, further including at least one first signal line extending from said socket second surface to said socket first surface, wherein said first signal trace is in electrical contact with said lid.

7. The microelectronic device package of claim 6, further including at least one external contact contacting said at least one first signal line proximate said socket second surface.

8. The microelectronic device package of claim 5, further including at least one second signal line extending from said socket second surface to said socket recess, wherein said second signal trace is in electrical contact with said substrate.

9. The microelectronic device package of claim 8, further including at least one external contact contacting said at least one second signal line proximate said socket second surface.

10. The microelectronic device package of claim 1, wherein said electrically conductive lid comprises dielectric lid having an electrically conductive signal trace proximate said lid attachment surface; and further comprising at least one electrically conductive first interconnect contacting said electrically conductive signal trace.

11. The microelectronic device package of claim 1, further comprising:
an electrically conductive signal trace proximate said lid attachment surface and a dielectric layer disposed between said electrically conductive signal trace and said lid attachment surface;
at least one electrically conductive second interconnect extending between said at least one electrically conductive signal trace and said substrate; and
said substrate having at least one second conductive trace extending between said electrically conductive second interconnect and said microelectronic die.

12. The microelectronic device package of claim 11, further including a second signal line in electrical communication with said at least one electrically conductive signal trace.

13. The microelectronic device package of claim 11, wherein said electrically conductive lid comprises thermally conductive heat dissipation device.

14. The microelectronic device package of claim 13, further comprising a thermal interface material disposed between said heat dissipation device and a back surface of said at least one microelectronic die.

15. The microelectronic device package of claim 11, further comprising:
a socket having a first surface, a second surface opposing said first surface; and a recess extending into said socket from said socket first surface;
said substrate and said microelectronic die substantially residing in said socket recess; and
a portion of said lid extending proximate said socket first surface.

16. The microelectronic device package of claim 15, further including at least one first signal line and at least one second signal line each extending from said socket second surface to said socket first surface, wherein said first signal trace is in electrical contact with said lid and wherein said third signal line is in electrical contact with said electrically conductive signal trace.

17. The microelectronic device package of claim 16, further including at least one external contact contacting said at least one first signal line proximate said socket second surface and at least one external contact contacting said at least one third signal line proximate said socket second surface.

18. The microelectronic device package of claim 15, further including at least one second signal line extending from said socket second surface to said socket recess, wherein said second signal trace is in electrical contact with said substrate.

19. The microelectronic device package of claim 18, further including at least one external contact contacting said at least one second signal line proximate said socket second surface.

20. An electronic system, comprising:
an external substrate within a housing; and
at least one microelectronic device package attached to said external substrate, including:
an electrically conductive lid having an attachment surface;
a substrate having an attachment surface;
at least one electrically conductive first interconnect extending between said lid attachment surface and said substrate attachment surface;
at least one microelectronic die disposed between said lid attachment surface and said substrate attachment surface; and
said substrate having at least one first conductive trace extending between said electrically conductive first interconnect and said microelectronic die; and
an input device interfaced with said external substrate; and
a display device interfaced with said external substrate.

21. The electronic system of claim 20, said microelectronic device package further including a first signal line in electrical communication with said electrically conductive lid.

22. The electronic system of claim 20, said microelectronic device package further comprising:
a socket having a first surface, a second surface opposing said first surface; and a recess extending into said socket from said socket first surface;
said substrate and said microelectronic die substantially residing in said socket recess; and
a portion of said lid extending proximate said socket first surface.

23. The electronic system of claim 22, said microelectronic device package further including at least one first signal line extending from said socket second surface to said socket first surface, wherein said first signal trace is in electrical contact with said lid.

24. The electronic system of claim 23, said microelectronic device package further including at least one external contact contacting said at least one first signal line proximate said socket second surface.

25. The electronic system of claim 22, said microelectronic device package further including at least one second signal line extending from said socket second surface to said socket recess, wherein said second signal trace is in electrical contact with said substrate.

26. The electronic system of claim 25, said microelectronic device package further including at least one external contact contacting said at least one second signal line proximate said socket second surface.

27. The electronic system of claim 20, wherein said electrically conductive lid comprises dielectric lid having an electrically conductive signal trace proximate said lid attachment surface; and further comprising at least one electrically conductive first interconnect contacting said electrically conductive signal trace.

28. The electronic system of claim 20, said microelectronic device package further comprising:
an electrically conductive signal trace proximate said lid attachment surface and a dielectric layer disposed between said electrically conductive signal trace and said lid attachment surface;
at least one electrically conductive second interconnect extending between said at least one electrically conductive signal trace and said substrate; and
said substrate having at least one second conductive trace extending between said electrically conductive second interconnect and said microelectronic die.

29. The electronic system of claim 28, said microelectronic device package further including a second signal line in electrical communication with said at least one electrically conductive signal trace.

30. The electronic system of claim 28, said microelectronic device package further comprising:
a socket having a first surface, a second surface opposing said first surface; and a recess extending into said socket from said socket first surface;
said substrate and said microelectronic die substantially residing in said socket recess; and
a portion of said lid extending proximate said socket first surface.

31. The electronic system of claim 30, said microelectronic device package further including at least one first signal line and at least one second signal line each extending from said socket second surface to said socket first surface, wherein said first signal trace is in electrical contact with said lid and wherein said third signal line is in electrical contact with said electrically conductive signal trace.

32. The electronic system of claim 31, said microelectronic device package further including at least one external contact contacting said at least one first signal line proximate said socket second surface and at least one external contact contacting said at least one third signal line proximate said socket second surface.

33. The electronic system of claim 30, said microelectronic device package further including at least one second signal line extending from said socket second surface to said socket recess, wherein said second signal trace is in electrical contact with said substrate.

34. The electronic system of claim 33, said microelectronic device package further including at least one external contact contacting said at least one second signal line proximate said socket second surface.

35. A method of delivering at least one signal to a microelectronic die, comprising:
providing an electrically conductive lid having an attachment surface;
providing a substrate having an attachment surface;
disposing at least one electrically conductive first interconnect extending between said lid attachment surface and said substrate attachment surface;
disposing at least one microelectronic die between said lid attachment surface and said substrate attachment surface;
providing at least one first conductive trace extending between said electrically conductive first interconnect and said microelectronic die; and
delivering a signal to said electrically conductive lid.

36. The method of claim 35, wherein providing said electrically conductive lid comprises providing thermally conductive heat dissipation device.

37. The method of claim 36, further comprising disposing a thermal interface material between said heat dissipation device and a back surface of said at least one microelectronic die.

38. The method of claim 35, further comprising:
providing a socket having a first surface, a second surface opposing said first surface; and a recess extending into said socket from said socket first surface; and
disposing said substrate and said microelectronic die substantially within said socket recess; wherein a portion of said lid extends proximate said socket first surface.

39. The method of claim 38, further including providing at least one first signal line extending from said socket second surface to said socket first surface, wherein said first signal trace is in electrical contact with said lid.

40. The method of claim 39, further including providing at least one external contact contacting said at least one first signal line proximate said socket second surface.

41. The method of claim 39, further including providing at least one second signal line extending from said socket second surface to said socket recess, wherein said second signal trace is in electrical contact with said substrate.

42. The method of claim 41, further including providing at least one external contact contacting said at least one second signal line proximate said socket second surface.

43. The method of claim 35, wherein providing said electrically conductive lid comprises providing a dielectric lid having an electrically conductive signal trace proximate said lid attachment surface; and further providing at least one electrically conductive first interconnect contacting said electrically conductive signal trace.

44. The method of claim 35, further comprising:
providing an electrically conductive signal trace proximate said lid attachment surface and a dielectric layer disposed between said electrically conductive signal trace and said lid attachment surface;
providing at least one electrically conductive second interconnect extending between said at least one electrically conductive signal trace and said substrate; and
providing said substrate having at least one second conductive trace extending between said electrically conductive second interconnect and said microelectronic die.

45. The method of claim 44, further including providing a second signal line in electrical communication with said at least one electrically conductive signal trace.

46. The method of claim 44, wherein said providing electrically conductive lid comprises providing thermally conductive heat dissipation device.

47. The method of claim 46, further comprising a thermal interface material disposed between said heat dissipation device and a back surface of said at least one microelectronic die.

48. The method of claim 46, further comprising:
a socket having a first surface, a second surface opposing said first surface; and a recess extending into said socket from said socket first surface;
said substrate and said microelectronic die substantially residing in said recess; and
a portion of said lid extending proximate said socket first surface.

49. The method of claim 48, further including at least one first signal line and at least one second signal line each extending from said socket second surface to said socket first surface, wherein said first signal trace is in electrical contact with said lid and wherein said third signal line is in electrical contact with said electrically conductive signal trace.

50. The method of claim 49, further including at least one external contact contacting said at least one first signal line proximate said socket second surface and at least one external contact contacting said at least one third signal line proximate said socket second surface.

51. The method of claim 46, further including at least one second signal line extending from said socket second surface to said socket recess, wherein said second signal trace is in electrical contact with said substrate.

52. The method of claim 51, further including at least one external contact contacting said at least one second signal line proximate said socket second surface.
